(19) United States
(12) Patent Application Publication
(10) Pub. No.: US 2026/0363078 A1
(43) Pub. Date: Nov. 12, 2026

(54) Omnidirectional Integrated Evaporator/Condenser for Cooling Electronic Packages

(71) Applicant: Apple Inc., Cupertino, CA (US)

(72) Inventors: Kamal Sikka, Fremont, CA (US); Arnab Choudhury, Fremont, CA (US); Qianying Wu, Sunnyvale, CA (US); Yuan Gao, Sunnyvale, CA (US); Sougata Hazra, Sunnyvale, CA (US); Christopher Perez, San Francisco, CA (US)

(21) Appl. No.: 19/405,003

(22) Filed: Dec. 1, 2025

Related U.S. Application Data
(60) Provisional application No. 63/802,195, filed on May 8, 2025.

(51) Int. Cl. H10W 40/73; H10W 90/00; H10W 72/00; H10W 72/30

(52) U.S. Cl. CPC H10W 40/73; H10W 90/00; H10W 72/07354; H10W 72/30; H10W 72/347; H10W 90/734

(57) ABSTRACT

Electronic assemblies that include closed-loop cooling systems are described in accordance with embodiments. In an embodiment, an electronic assembly includes a routing substrate, an electronic package mounted on the routing substrate, a closed-loop cooling system mounted on the electronic package, and a cold plate mounted on the closed-loop cooling system. Further, the closed-loop cooling system may include an evaporator chamber bonded to the electronic package, and a condenser chamber that surrounds the evaporator chamber. In such embodiments, perforations in the walls of the evaporator chamber may provide pathways for vapor to move omnidirectionally from the evaporator chamber to the condenser chamber.

### RELATED APPLICATIONS

This application claims the benefit of priority of U.S. Provisional Application No. 63/802,195, filed May 8, 2025, which is herein incorporated by reference.

### BACKGROUND

### Field

Embodiments described herein relate to semiconductor packaging, more particularly to cooling systems.

### Background Information

Data centers are currently experiencing unprecedented demand due to the rapid expansion of digital services, cloud computing and artificial intelligence (AI). AI in particular has brought about a fundamental shift in computing requirements, where the training and inference of large AI models require massive computational resources that vastly exceed traditional workloads. To meet the demand, modern chips are becoming more powerful through increased transistor density, higher core counts, higher clock speeds and more complex architecture. During intensive computational workloads, these advanced chips can generate a tremendous amount of heat, which can lead to thermal throttling, reduced lifespan, potential hardware damage as well as other issues that may affect data center efficiency. To address these issues, data centers are becoming more efficient and environmentally conscious by implementing dynamic power management, advanced rack designs, and more efficient cooling systems.

### SUMMARY

Embodiments describe electronic assemblies that include a routing substrate, an electronic package mounted on the routing substrate, a closed-loop cooling system mounted on a top side of the electronic package and a cold plate mounted on the closed-loop cooling system. Further, the closed-loop cooling system may include an evaporator chamber bonded to the electronic package, a liquid inlet to inject liquid droplets into the evaporator chamber, a condenser chamber that surrounds the evaporator chamber and an outlet on the condenser chamber that connects to a fluid path to recirculate fluid back to the inlet of the evaporator chamber. In such embodiments, the condenser chamber may be annular so that the condenser chamber may be integrated with and surround the evaporator chamber. Further, perforations in the walls of the evaporator chamber that separate the evaporator chamber from the condenser chamber may act as pathways through which vapor may move omnidirectionally from the evaporator chamber to the condenser chamber.

### BRIEF DESCRIPTION OF THE DRAWINGS

FIG. 1A is a cross-sectional side view illustration of an electronic assembly that includes a closed-loop cooling system mounted on an electronic package in accordance with embodiments.

FIG. 1B is a cross-sectional side view illustration of the electronic assembly illustrated in FIG. 1A rotated 90 degrees in accordance with embodiments.

FIG. 2A is a cross-sectional side view illustration of a closed-loop cooling system during a first phase of a cooling cycle in accordance with embodiments.

FIG. 2B is a cross-sectional side view illustration of a closed-loop cooling system during a second phase of a cooling cycle in accordance with embodiments.

FIG. 2C is a cross-sectional side view illustration of a closed-loop cooling system during a third phase of a cooling cycle in accordance with embodiments.

FIG. 2D is a cross-sectional side view illustration of a closed-loop cooling system during a fourth phase of a cooling cycle in accordance with embodiments.

FIG. 3A is a top view illustration of multiple closed-loop cooling systems mounted on multiple electronic packages, respectively, in accordance with embodiments.

FIG. 3B is a top view illustration of a closed-loop cooling system that spans multiple electronic packages in accordance with embodiments.

### DETAILED DESCRIPTION

Data centers house increasingly powerful processors that generate extraordinary amounts of heat during operation, creating critical thermal management challenges for facility designers and operators. To address these thermal management challenges, some data centers implement air cooling methods. Conventional air cooling methods include passive heat sinks that dissipate heat through metal fins, active air cooling using fans that force air across heat sinks, raised floor designs that deliver cold air from below, computer room air conditioning (CRAC) units designed to maintain precise temperature and humidity levels, etc. However, air cooling methods have several limitations, such as significant space requirements for air handling equipment, high energy consumption for fans and chillers, difficulty managing hotspots in dense graphics processing unit (GPU) clusters, etc.

Modern data centers have shifted to implement water cooling methods to address thermal management challenges. One water cooling method is cold plate cooling in which a cold plate attaches directly to a chip/package (e.g., central processing units (CPU), GPU, etc.), a cooling fluid passes through the channels of the cold plate to absorb heat directly from the chip surface, and the heated fluid is then pumped away to separate cooling systems to be cooled before recirculation. However, it has been observed that the flow rate and velocity of the cooling fluid require careful management and that the differences in the coefficient of thermal expansion between the different materials (e.g., chip, cold plate, mounting hardware, etc.) can cause mechanical stress and potential misalignment over time. Another water cooling method is two-phase cooling in which the phase change of the cooling fluid from liquid to vapor occurs directly over the chip surface, and the vapor produced by the heat from multiple chips/packages is routed to a remote condenser unit that changes the vapor back to a liquid state to be recirculated through the water cooling system. However, it has been observed that such remote condenser units may have substantial space requirements and may act as a potential bottleneck for the entire cooling system during high-demand periods, representing a singular point of failure risk if the condenser units are centralized.

In embodiments, an electronic assembly may include a closed-loop cooling system with an integrated evaporator/condenser bonded to an electronic package (e.g., system-on-chip, etc.). In such instances, the condenser chamber is annular so as to surround the evaporator chamber so that both the evaporator and the condenser may be located locally over the electronic package. In addition, a cold plate may be mounted to a distal condenser surface of the condenser chamber to cause the phase change from vapor to liquid, where the liquid may then be recirculated through a fluid path that connects an outlet of the condenser chamber to an inlet of the evaporator chamber. In this way, the phase change from vapor to liquid may occur locally (over the electronic package) as opposed to conventional methods in which the condenser may be located remotely (away from the electronic package). Further, the walls of the evaporator chamber that separate an interior region of the evaporator chamber from an interior region of the condenser chamber may be perforated. The perforations allow the vapor from the evaporator chamber to move to the condenser chamber in an omnidirectional manner, which increases the efficiency with which the electronic package may be cooled.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

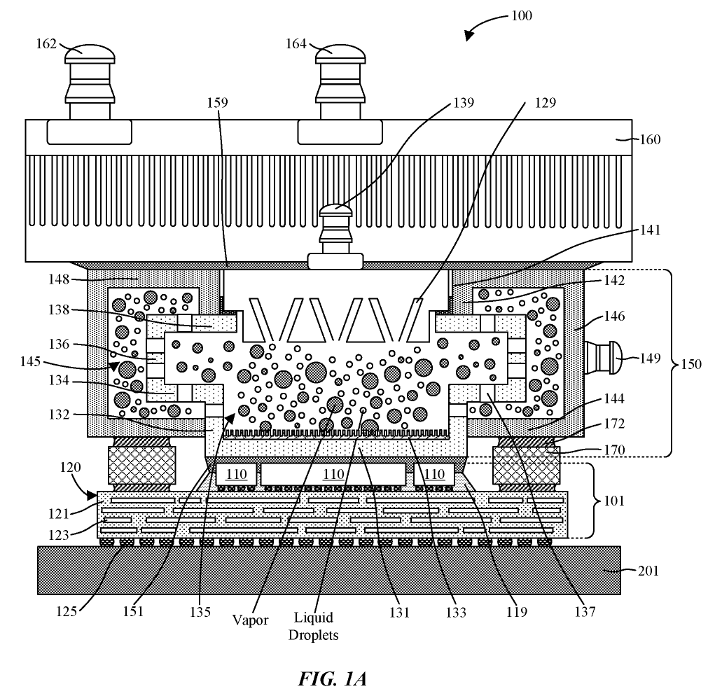

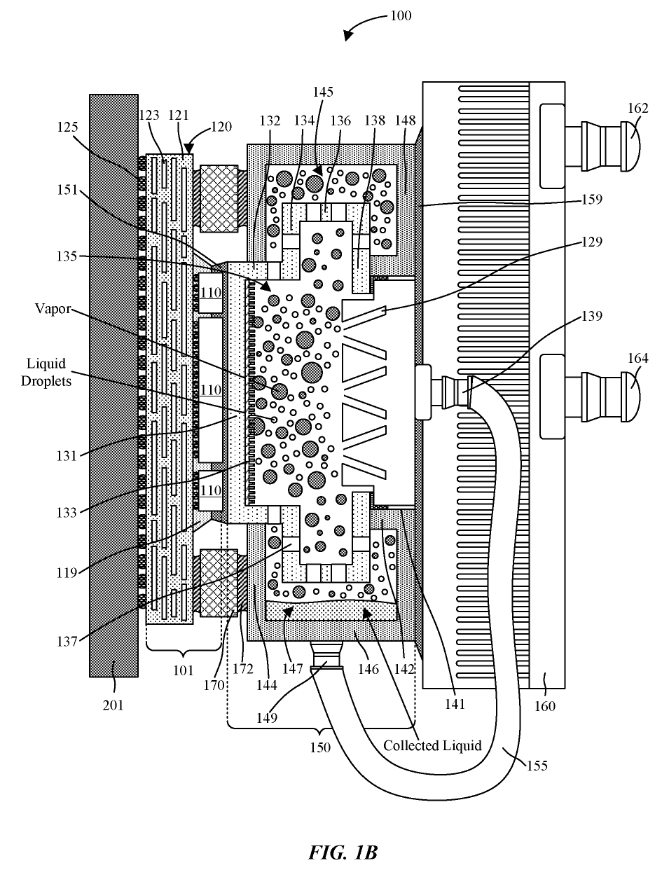

Referring now to FIGS. 1A-1B, FIG. 1A is a cross-sectional side view illustration of an electronic assembly that includes a closed-loop cooling system mounted on an electronic package in accordance with embodiments; FIG. 1B is a cross-sectional side view illustration of the electronic assembly illustrated in FIG. 1A rotated 90 degrees in accordance with embodiments. As shown in FIGS. 1A-1B, electronic assembly 100 may include an electronic package 101 mounted to a module substrate 201 (e.g., printed circuit board (PCB), etc.). Electronic package 101 may include a plurality of electronic components 110 bonded to routing layer 120 by any suitable method (e.g., flip-chip bonding, hybrid bonding, etc.), where the plurality of electronic components 110 may be an integrated circuit die, logic, memory (e.g., dynamic random-access memory (DRAM), high bandwidth memory (HBM), double data rate (DDRx), low-power double data rate (LPDDRx), etc. Various exemplary dies (or packages) may include system-on-chip (SoC), graphics processing unit (GPU), central processing unit (CPU), artificial intelligence (AI), machine learning logic, radio-frequency (RF) baseband processor, signal processors, power management integrated circuit (PMIC), logic, memory, photonics, biochips, low speed and/or high speed input/output (HSIO), cache, a silicon interconnect, system-in-package (SiP), etc., and any combinations thereof.

In further reference to FIGS. 1A-1B, electronic package 101 may include routing layer 120. Routing layer 120 may be formed by a layer-by-layer process and may be formed using thin film technology. Routing layer 120 may include one or more dielectric layers 121 and one or more redistribution lines 123. The one or more dielectric layers 121 may be formed by standard deposition techniques (e.g., lamination, spin coating, spray coating, physical vapor deposition, chemical vapor deposition, etc.) and may include any suitable materials. The one or more redistribution lines 123 may be embedded (e.g., embedded traces) in the one or more dielectric layers 121, and may include, but are not limited to, metallic materials such as copper, titanium, nickel, gold, and combinations or alloys thereof. Further, routing layer 120 may include a passivation layer (e.g., low temperature polyimide (“LTPI”), etc.) on the back side of routing layer 120, where the back side of routing layer 120 may also include under bump metallization (UBM) pads and solder joints, such as solder joints 125 that bond electronic package 101 to module substrate 201 by any suitable bonding method (e.g., surface mount technology).

Referring still to FIGS. 1A-1B, the plurality of electronic components 110 may be bonded to routing layer 120 by any suitable method, such as flip-chip bonding, hybrid bonding, etc. or any combination thereof. In some embodiments, electronic package 101 may be packaged according to a “chip first” approach in which the plurality of electronic components 110 are diced and encapsulated within a gap fill material to form a reconstituted wafer or panel, where the routing layer may then be formed on the reconstituted wafer to create a direct electrical connection between the plurality of electronic components and the embedded traces (e.g., one or more redistribution lines 123) of the routing layer. In other embodiments, electronic package 101 may be packaged according to a “chip last” approach in which the plurality of electronic components are bumped and bonded to a routing layer, where the electronic package 101 may further include an optional gap fill material to encapsulate the plurality of electronic components and/or an optional underfill between the plurality of electronic components and the routing layer. In the embodiment illustrated in FIGS. 1A-1B, electronic package 101 includes underfill 119 between the plurality of electronic components 110 and routing layer 120. In other embodiments still, the plurality of electronic components may be directly bonded (e.g., hybrid bonded, fusion bonded, etc.) to routing layer 120.

In further reference to FIG. 1A, electronic assembly 100 may also include closed-loop cooling system 150 mounted on electronic package 101. The closed-loop cooling system includes an evaporator and condenser integrated into a single cooling device where condensation may occur locally (near the electronic package) by the closed-loop cooling system, as opposed to conventional methods where condensation may be performed remotely (away from the electronic package) by a separate condensation unit. As illustrated in FIG. 1A, closed-loop cooling system 150 may include evaporator chamber 130. Evaporator chamber 130 may be any suitable material (e.g., copper, stainless steel, titanium, sheet metal, etc.), where such material may include additional protective treatments for water exposure. In an embodiment, evaporator chamber 130 is sheet metal. In addition, evaporator chamber 130 may include a base that is proximal to electronic package 101, such as proximal evaporator surface 131, that may be bonded to electronic package 101 by thermal interface material 151 (e.g., thermal adhesive, thermal paste, etc.). In such instances, heat generated by electronic package 101 may be conducted through thermal interface material 151 and proximal evaporator surface 131 and into an interior region of evaporator chamber 130, such as interior evaporator region 135. In some embodiments, proximal evaporator surface 131 may span the width of electronic package 101 so that the width of proximal evaporator surface 131 is the same or substantially similar to the width of routing layer 120. In other embodiments, proximal evaporator surface 131 may span only a portion of electronic package 101. For example, as shown in FIG. 1A, proximal evaporator surface 131 spans the plurality of electronic components 110 bonded to electronic package 101. Further, proximal evaporator surface 131 may include a wicking structure (e.g., wire mesh, micropillar arrays, etc.), such as wicking structure 133, to wick fluid away from electronic package 101 and enhance bubble formation.

In further reference to FIG. 1A, evaporator chamber 130 may include a distal evaporator surface, such as distal evaporator surface 138, located opposite to proximal evaporator surface 131. Further, distal evaporator surface 138 may include a liquid inlet, such as liquid inlet 139, to inject liquid droplets into the evaporator chamber, where the liquid droplets may be further propelled into the evaporator chamber by a fluid distribution element 129 (e.g., spray nozzles, converging jet nozzles, inlet holes, etc.). In such instances, fluid distribution element 129 may include mechanisms to prevent vapor backflow and ensure proper one-way directional flow into evaporator chamber 130, where such mechanisms may include check valves, pressure differentials, tapered nozzle designs, etc. Evaporator chamber 130 may further include sidewalls located between proximal evaporator surface 131 and distal evaporator surface 138, where the sidewalls further define the interior region of evaporator chamber 130 (e.g., interior evaporator region 135, etc.), which may be structured to form any standard or non-standard configuration. For example, the sidewalls of evaporator chamber 130 may be orthogonal, parallel, angled, tapered, stepped, contoured, baffled, etc., or any combination thereof in relation to proximal evaporator surface 131 and/or distal evaporator surface 138. In the embodiment shown in FIG. 1A, evaporator chamber 130 forms a “T” shape that includes evaporator sidewalls 132, 134, 136, where evaporator sidewalls 132 and 136 are orthogonal to both proximal evaporator surface 131 and distal evaporator surface 138, and evaporator sidewall 134 is parallel to both proximal evaporator surface 131 and distal evaporator surface 138.. Further, evaporator chamber 130 may include perforations. For example, as shown in FIG. 1A, evaporator sidewalls, 132, 134, 136 and distal evaporator surface 138 include perforations 137 (e.g., holes, membrane, etc.). In such instances, the perforations provide a pathway for vapor to move omnidirectionally (e.g., x-y-z directions, etc.) from evaporator chamber 130 to condenser chamber 140. In the example of FIG. 1A, vapor may move through perforations 137 in evaporator sidewalls 132, 134, 136 and distal evaporator surface 138. Further still, perforations 137 may be of any number, size, shape or arrangement to maintain the proper vapor flow and pressure differentials needed for the closed-loop cooling system to function efficiently.

In further reference to FIG. 1A, condenser chamber 140 may be annular so that the walls of condenser chamber 140 surround the walls of evaporator chamber 130. In this way, the inner evaporator chamber may be surrounded by (and integrated with) the outer condenser chamber to form a single cooling device where the perforated walls of the evaporator chamber provide a boundary between the evaporator chamber from the condenser chamber. Condenser chamber 140 may be any suitable material (e.g., copper, stainless steel, titanium, sheet metal, etc.), where such material may include additional protective treatments for water exposure. Further, condenser chamber 140 may include a surface proximal to electronic package 101, such as proximal condenser surface 144. Stiffeners 170 may be located between proximal condenser surface 144 and routing layer 120 to provide mechanical support for condenser chamber 140, where stiffeners 170 may be bonded to both routing layer 120 and proximal condenser surface 144 by an adhesive (e.g., epoxy-based adhesives, etc.) such as adhesive 172. Further still, condenser chamber 140 may include a surface distal from electronic package 101 and located opposite to proximal condenser surface 144, such as distal condenser surface 148. Cold plate 160 may be bonded to distal condenser surface 148 by thermal interface material 159 (e.g., thermal adhesive, thermal paste, etc.), where cold plate 160 cools the walls and interior region (e.g., interior condenser region 145) of condenser chamber 140 so that the vapor in condenser chamber 140 changes back to a liquid state. In addition, cold plate 160 may include its own respective liquid inlets and outlets, such as inlet 162 and outlet 164.

In further reference to FIG. 1A, condenser chamber 140 may include sidewalls located between proximal condenser surface 144 and distal condenser surface 148, where the sidewalls may be structured to form any standard or non-standard configuration to surround the evaporator chamber. For example, the sidewalls may be orthogonal, parallel, angled, tapered, stepped, contoured, baffled, etc., or any combination thereof in relation to proximal condenser surface 144 and/or distal condenser surface 148. In addition, condenser chamber 140 may be structured to include an interior region, such as interior condenser region 145, between the walls of condenser chamber 140 and the corresponding walls of evaporator chamber 130. For example, in the embodiment illustrated in FIG. 1A, condenser chamber 140 includes proximal condenser surface 144, condenser sidewalls 142, 146, and distal condenser surface 148, where interior condenser region 145 includes the space between proximal condenser surface 144 and evaporator sidewall 134, condenser sidewall 146 and evaporator sidewall 136, and distal condenser surface 148 and distal evaporator surface 138. In this way, the structure of the integrated evaporator/condenser allows for the omnidirectional flow of vapor through perforations 137. Further, condenser sidewall 142 may have an inner perimeter 141 that corresponds to and surrounds/encompasses a footprint of the plurality of electronic components 110.

Referring now to FIG. 1B, FIG. 1B is substantially similar to the embodiment shown in FIG. 1A except electronic assembly 100 has been rotated 90 degrees. In practice, high-density computing environments where thermal management is critical may include computing systems that are vertically mounted (e.g., blade server systems, rack-mounted servers, network switches and routers, etc.), which provide better airflow for cooling, more efficient use of space within standard rack configurations and easier access for installation and maintenance. Consequently, the electronic assemblies that are part of such computing systems, such as electronic assembly 100, may also be oriented vertically as illustrated in FIG. 1B. The vertical orientation of electronic assembly 100 allows for gravity to naturally cause the fluid to collect in a collection region, such as liquid collection region 147, near liquid outlet 149 of condenser chamber 140. In the embodiment illustrated in FIG. 1B, liquid outlet 149 is located on condenser sidewall 146 of condenser chamber 140. In other embodiments, the liquid outlet(s) may be located alternatively or additionally on the other surfaces of condenser chamber 140 (e.g., proximal condenser surface 144, etc.) to facilitate the removal of liquid collected in liquid collection region 147. Further, the liquid may then be recirculated via pump, capillary action, etc. through a fluid path (e.g., tube, etc.), such as fluid path 155, from liquid outlet 149 of condenser chamber 140 to liquid inlet 139 of evaporator chamber 130. In this way, by recirculating the liquid locally through closed-loop cooling system 150, electronic assembly 100 may offer cooling efficiency and energy efficiency that is higher than conventional air-cooled systems or water-cooled cooling systems in which recirculation may necessitate a remote/centralized condenser unit.

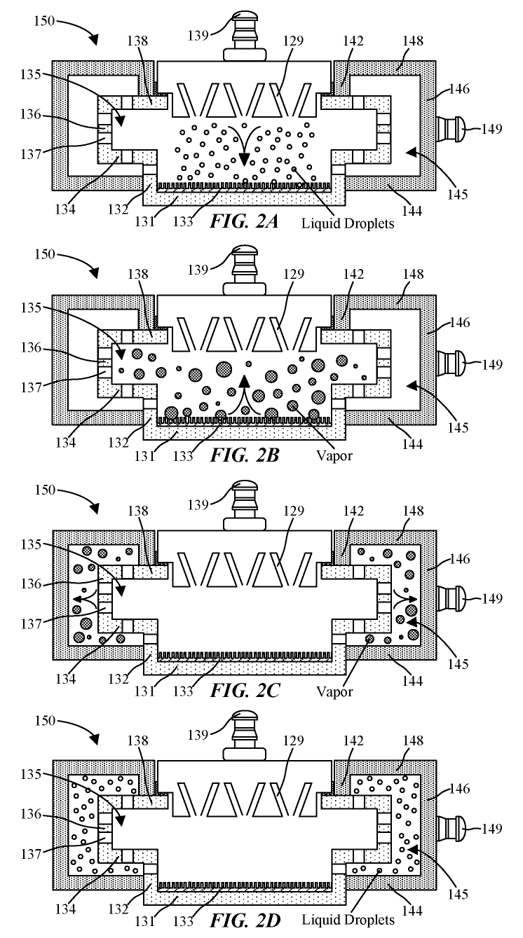

Referring now to FIGS. 2A-2D, a cross-sectional side view illustration of closed-loop cooling system 150 is shown for each phase of a cooling cycle in accordance with embodiments. It should be noted that evaporator chamber 130 and condenser chamber 140 may include a steady mixture of both vapor and liquid phases during operation of closed-loop cooling system 150, as illustrated in FIGS. 1A-1B. But in the interest of clarity, the vapor and liquid phases are shown sequentially during a typical cooling cycle, as illustrated in FIGS. 2A-2D. In FIG. 2A, liquid droplets enter interior evaporator region 135 of evaporator chamber 130 through liquid inlet 139 where the liquid droplets may be propelled toward proximal evaporator surface 131 of evaporator chamber 130 by fluid distribution element 129 (e.g., spray nozzles, converging jet nozzles, inlet holes, etc.), where proximal evaporator surface 131 may include wicking structure 133 to wick fluid away from electronic package 101 and enhance bubble formation. Further, heat generated by the electronic package and conducted through proximal evaporator surface 131 of evaporator chamber 130 causes the liquid droplets to boil and thereby change to a vapor state as illustrated in FIG. 2B. The vapor may then flow omnidirectionally from evaporator chamber 130 to interior condenser region 145 of condenser chamber 140. For example, the vapor may flow through perforations 137 in evaporator sidewalls 132, 134, 136 and distal evaporator surface 138 as illustrated in FIG. 2C. After the vapor flows to condenser chamber 140, cold plate 160 (not illustrated) bonded to distal condenser surface 148 of condenser chamber 140 causes the vapor to change phase back to a liquid and exit condenser chamber 140 through liquid outlet 149.

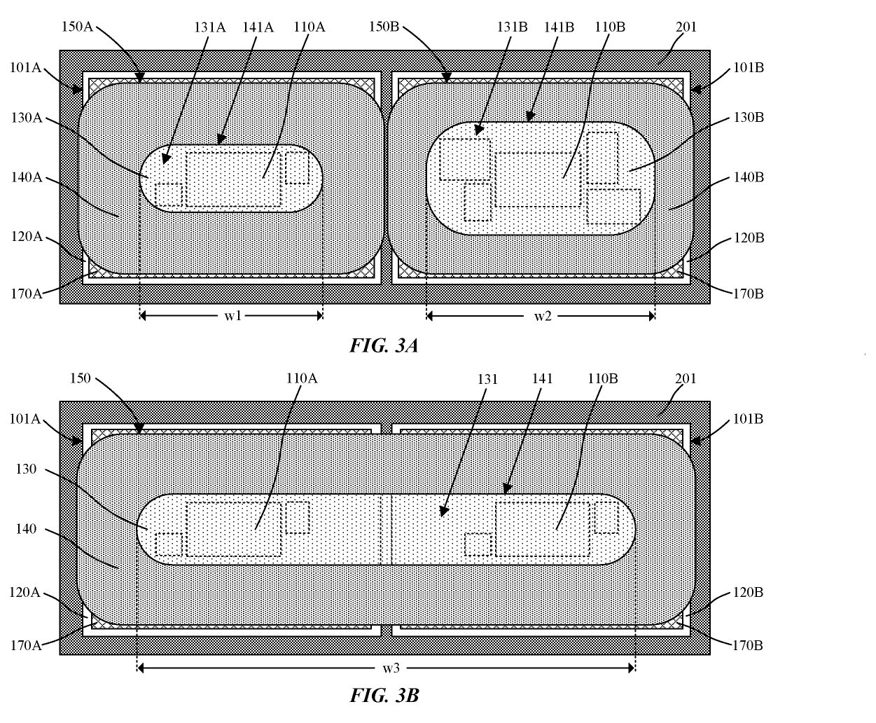

Referring now to FIGS. 3A-3B, FIG. 3A is a top view illustration of multiple closed-loop systems mounted on multiple electronic packages, respectively, in accordance with embodiments; FIG. 3B is a top view illustration of a closed-loop cooling system that spans multiple electronic packages in accordance with embodiments. In embodiments, the condenser chamber may be structured to form any annular shape (e.g., circular, elliptical, rectangular, etc.). For example, in the embodiments illustrated in FIGS. 3A-3B, the condenser chambers form a rectangular annular shape. It should be noted that different annular shapes for the condenser chamber (e.g., circular, elliptical, rectangular, etc.) may be included on the same routing substrate in any combination. Further, routing substrate 201 may include a plurality of electronic packages, such as first electronic package 101A that includes a first plurality of electronic components 110A mounted on routing layer 120A as well as second electronic package 101B that includes a second plurality of electronic components 110B mounted on routing layer 120B, as illustrated in FIGS. 3A-3B.

In some embodiments, electronic assembly 100 may include individual closed-loop cooling systems for each individual electronic package, respectively, as illustrated in FIG. 3A. In such embodiments, the dimensions of each closed-loop cooling system may correspond to (and vary by) the characteristics of the electronic package to be cooled (e.g., package footprint, die count, etc.) so that each closed-loop cooling system may be specific to each electronic package. For example, as illustrated in FIG. 3A, evaporator chamber 130A of first closed-loop cooling system 150A may be structured so that proximal evaporator surface 131A has a first width, w1, that corresponds to a footprint of the first plurality of electronic components 110A bonded to routing layer 120A of first electronic package 101A, and evaporator chamber 130B of second closed-loop cooling system 150B may be structured so that proximal evaporator surface 131B has a second width, w2, that corresponds to a footprint of the second plurality of electronic components 110B bonded to routing layer 120B of second electronic package 101B, where the first width, w1, is different from the second width, w2. Similarly, condenser chamber 140A of first closed-loop cooling system 150A may be structured so that inner perimeter 141A corresponds to (and surrounds/encompasses) the footprint of the first plurality of electronic components 110A bonded to routing layer 120A of first electronic package 101A, and condenser chamber 140B of second closed-loop cooling system 150B may be structured so that inner perimeter 141B corresponds to (and surrounds/encompasses) the footprint of the second plurality of electronic components 110B bonded to routing layer 120B of second electronic package 101B. In such instances, closed-loop cooling system 150A may include stiffener 170A to support condenser chamber 140A, and closed-loop cooling system 150B may include stiffener 170B to support condenser chamber 140B.

In other embodiments, electronic assembly 100 may include an individual closed-loop cooling system that spans multiple electronic packages, as illustrated in FIG. 3B. In this way, an individual closed-loop cooling system may be “shared” across multiple electronic packages. For example, as illustrated in FIG. 3B, closed-loop cooling system 150 may be structured so that proximal evaporator surface 131 of evaporator chamber 130 has a width, w3, that spans across the first plurality of electronic components 110A bonded to routing layer 120A of first electronic package 101A as well as the second plurality of electronic components 110B bonded to routing layer 120B of second electronic package 101B. Similarly, closed-loop cooling system 150 may be structured so that inner perimeter 141 of condenser chamber 140 corresponds to (and surrounds/encompasses) a footprint that includes the first plurality of electronic components 110A bonded to routing layer 120A of first electronic package 101A as well as the second plurality of electronic components 110B bonded to routing layer 120B of second electronic package 101B. Further, stiffener 170A may support condenser chamber 140 on electronic package 101A and stiffener 170B may support condenser chamber 140 on electronic package 101B. In addition, it should be noted that both individualized closed-loop cooling systems, such as the closed-loop cooling systems 150A, 150B illustrated in FIG. 3A, as well as “shared” closed-loop cooling systems, such as the closed-loop cooling system 150 illustrated in FIG. 3B, may be included on the same routing substrate and in any combination.

In utilizing the various aspects of the embodiments, it would become apparent to one skilled in the art that combinations or variations of the above embodiments are possible for forming an electronic assembly that includes a closed-loop cooling system. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic assembly comprising:
a routing substrate;
an electronic package mounted on the routing substrate;
a closed-loop cooling system mounted on a top side of the electronic package, the closed-loop cooling system comprising:
an evaporator chamber bonded to the electronic package, wherein the evaporator chamber includes perforated walls and a liquid inlet to inject liquid droplets into the evaporator chamber; and
a condenser chamber that surrounds the evaporator chamber, wherein the condenser chamber includes a liquid outlet; and
a cold plate mounted on the closed-loop cooling system.

2. The electronic assembly of claim 1, wherein perforations in the perforated walls of the evaporator chamber provide pathways for vapor to move omnidirectionally from the evaporator chamber to the condenser chamber.

3. The electronic assembly of claim 1, wherein the perforated walls include evaporator sidewalls and a distal evaporator surface that form an interior evaporator region of the evaporator chamber.

4. The electronic assembly of claim 3, wherein the condenser chamber surrounds the evaporator sidewalls and the distal evaporator surface to form an interior condenser region, the interior condenser region including a liquid collection region.

5. The electronic assembly of claim 1, wherein the cold plate contacts a distal condenser surface of the condenser chamber.

6. The electronic assembly of claim 1, wherein the closed-loop cooling system includes a fluid path from the liquid outlet of the condenser chamber to the liquid inlet of the evaporator chamber.

7. The electronic assembly of claim 1, wherein the evaporator chamber includes a proximal evaporator surface, the proximal evaporator surface being located over a plurality of electronic components that are part of the electronic package and bonded to the electronic package by a thermal interface material.

8. The electronic assembly of claim 7, wherein the evaporator chamber includes a wicking structure located on the proximal evaporator surface.

9. The electronic assembly of claim 1, wherein the routing substrate includes a plurality of electronic packages, the plurality of electronic packages including at least a first electronic package and a second electronic package.

10. The electronic assembly of claim 9, wherein a first closed-loop cooling system is mounted to a top side of the first electronic package, and a second closed-loop cooling system is mounted to a top side of the second electronic package.

11. The electronic assembly of claim 10, where in a first size of the first closed-loop cooling system corresponds to a first footprint of the first electronic package, and a second size of the second closed-loop cooling system corresponds to a second footprint of the second electronic package, the first size being different from the second size.

12. The electronic assembly of claim 9, wherein the closed-loop cooling system spans the first electronic package and the second electronic package.

13. The electronic assembly of claim 12, wherein an inner perimeter of the condenser chamber corresponds to and surrounds a footprint that includes a first plurality of electronic components bonded to the first electronic package and a second plurality of electronic components bonded to the second electronic package.

14. A closed-loop cooling system comprising:
an evaporator chamber than includes perforated walls and a liquid inlet on the evaporator chamber to inject liquid droplets into the evaporator chamber; and
a condenser chamber that surrounds the evaporator chamber, wherein the condenser chamber includes a liquid outlet.

15. The closed-loop cooling system of claim 14, wherein perforations in the perforated walls of the evaporator chamber provide pathways for vapor to move omnidirectionally from the evaporator chamber to the condenser chamber.

16. The closed-loop cooling system of claim 14, wherein the perforated walls include evaporator sidewalls and a distal evaporator surface that form an interior evaporator region of the evaporator chamber.

17. The closed-loop cooling system of claim 16, wherein the condenser chamber surrounds the evaporator sidewalls and the distal evaporator surface to form an interior condenser region, the interior condenser region including a liquid collection region.

18. The closed-loop cooling system of claim 14, further comprising a fluid path from the liquid outlet of the condenser chamber to the liquid inlet of the evaporator chamber.

19. The closed-loop cooling system of claim 14, wherein the evaporator chamber includes a proximal evaporator surface, the proximal evaporator surface including a wicking structure.

20. The closed-loop cooling system of claim 14, wherein the liquid inlet includes a spray nozzle, converging jet nozzles, or inlet holes.
